(19) United States
(12) Patent Application Publication
(10) Pub. No.: US 2026/0334175 A1
(43) Pub. Date: Oct. 22, 2026

(54) PATTERNABLE BONDED WAFER METALLIC GETTERING USING EPITAXIAL STACKING FAULTS

(71) Applicant: Renesas Electronics America Inc., Milpitas, CA (US)

(72) Inventor: Robert Joseph KINZIG, Melbourne (FL)

(73) Assignee: Renesas Electronics America Inc., Milpitas, CA (US)

(21) Appl. No.: 19/184,381

(22) Filed: Apr. 21, 2025

(51) Int. Cl. H01L 21/762; H10D 62/00; H10D 86/00; H10D 86/01

(52) U.S. Cl. CPC H10P 90/1914; H10D 62/01; H10D 86/01; H10D 86/201; H10W 10/181

(57) ABSTRACT

A method of forming a semiconductor structure includes forming a first epitaxial layer on a first side of a first wafer opposing a second side, the first epitaxial layer includes a plurality of stacking faults. A first oxide is formed on both sides of the first wafer. The first wafer is bonded to a second wafer via the first oxide and flipped. A thinning process is conducted on the second side to expose its upper surface. A buried layer is formed within the first wafer. A second epitaxial layer is formed above the exposed upper surface and the buried layer. A trench feature is formed through a device layer formed by the first epitaxial layer, the first wafer, and the second epitaxial layer to the first oxide and filled with a polysilicon via a second oxide. A transistor region is formed above the buried layer.

### BACKGROUND

The present disclosure generally relates to the field of semiconductor device fabrication, and more particularly to wafer-level bonding techniques.

Silicon-On-Insulator (SOI) technology has become a fundamental approach in semiconductor fabrication, offering improved device performance, reduced power consumption, and enhanced isolation compared to bulk silicon substrates. SOI wafers consist of a thin silicon device layer separated from a supporting handle wafer by a buried insulating layer, typically silicon dioxide (SiO₂). This structure provides advantages such as minimized parasitic capacitance, better thermal management, and increased scalability for advanced semiconductor applications.

Wafer bonding is a key technique for producing SOI wafers, enabling the integration of the thin silicon device layer onto an insulating substrate. Various bonding methods are employed, including direct bonding, in which two wafers are joined through molecular adhesion, and adhesive bonding, which utilizes an intermediate bonding layer. The process often includes high-temperature annealing steps to strengthen the bond, followed by thinning of the device wafer to achieve the desired silicon thickness. SOI wafer bonding is widely used in applications such as high-speed digital circuits, radio-frequency (RF) devices, and Micro-Electro-Mechanical Systems (MEMS), where improved electrical isolation and performance characteristics are essential.

Despite these advantages, the SOI wafer bonding process faces several challenges. For instance, metallic contaminants (originating from processing equipment, handling procedures, or residual impurities on wafer surfaces) can severely degrade the device wafer. Such contamination can disrupt interfacial chemistry, leading to defect formation, diminished electrical performance, and long-term reliability issues. As SOI technology continues to evolve, addressing these challenges remains essential for improving manufacturing efficiency and device performance.

### SUMMARY

According to an embodiment of the present disclosure, a method of forming a semiconductor structure includes forming a first epitaxial layer on a first side of a first wafer, the first side opposing a second side, the first epitaxial layer including a plurality of stacking faults, forming a first oxide layer on the first side of the first wafer and on the second side of the first wafer, bonding the first wafer to a second wafer via the first oxide layer on the first side of the first wafer, flipping the first wafer bonded to the second wafer, conducting a thinning process on the second side of the first wafer, the thinning process exposing an upper surface of the second side of the first wafer, forming a buried layer within the first wafer, forming a second epitaxial layer above the upper surface of the first wafer and above the buried layer, with the first epitaxial layer, the first wafer and the second epitaxial layer forming a device layer of the semiconductor structure, forming a trench feature adjacent to the buried layer, the trench feature extending through the device layer until reaching an upper surface of the first oxide layer, filling an inside of the trench feature with a polysilicon layer via a second oxide layer, and forming a transistor region above the buried layer.

According to another embodiment of the present disclosure, a method of forming a semiconductor structure includes forming point defects at predefined areas of a first side of a first wafer, the first wafer having a second side opposing the first side, epitaxially growing a first epitaxial layer on the first side of the first wafer, with a stacking fault being formed at each point defect located at an interface between the first wafer and the first epitaxial layer, the stacking fault propagating upward through the first epitaxial layer, forming a first oxide layer on the first side of the first wafer and on the second side of the first wafer, bonding the first wafer to a second wafer via the first oxide layer on the first side of the first wafer, flipping the first wafer bonded to the second wafer, conducting a thinning process on the second side of the first wafer, the thinning process exposing an upper surface of the second side of the first wafer, forming a buried layer within the first wafer, forming a second epitaxial layer above the upper surface of the first wafer and above the buried layer, with the first epitaxial layer, the first wafer and the second epitaxial layer forming a device layer, forming a trench feature adjacent to the buried layer, the trench feature extending through the device layer until reaching an upper surface of the first oxide layer, filling an inside of the trench feature with a polysilicon layer via a second oxide layer, and forming a transistor region above the buried layer.

According to yet another embodiment of the present disclosure, a semiconductor structure includes a first wafer including a device layer on a first side, the first wafer having a second side opposing the first side, with the device layer including a plurality of stacking faults positioned on a bottom portion of the device layer, a buried layer positioned within the device layer above the plurality of stacking faults, and transistor region electrically connected to the buried layer, and a second wafer bonded to the first side of the first wafer via a first oxide layer.

### BRIEF DESCRIPTION OF THE DRAWINGS

The following detailed description, given by way of example and not intended to limit the embodiments described herein, will best be appreciated in conjunction with the accompanying drawings, in which:

FIG. 1 is a cross-sectional view of a semiconductor structure at an initial step during a wafer bonding process, according to an embodiment of the present disclosure;

FIG. 2 is a cross-sectional view of the semiconductor structure after forming a first epitaxial layer with stacking faults, according to an embodiment of the present disclosure;

FIG. 3 is a cross-sectional view of the semiconductor structure after forming a first oxide layer and a second oxide layer, according to an embodiment of the present disclosure;

FIG. 4 is a cross-sectional view of the semiconductor structure after bonding a device wafer 102 to a handle wafer and flipping the device wafer, according to an embodiment of the present disclosure;

FIG. 5 is a cross-sectional view of the semiconductor structure after grinding and polishing the device wafer to a final thickness and forming a first buried layer within the device wafer, according to an embodiment of the present disclosure;

FIG. 6 is a cross-sectional view of the semiconductor structure after oxidizing the first buried layer and forming a second buried layer within the device wafer, according to an embodiment of the present disclosure;

FIG. 7 is a cross-sectional view of the semiconductor structure after forming a second epitaxial layer above the device wafer, according to an embodiment of the present disclosure;

FIG. 8 is a cross-sectional view of the semiconductor structure after forming first and second sinker regions and etching trench features, according to an embodiment of the present disclosure;

FIG. 9 is a cross-sectional view of a region of the semiconductor structure after forming a polysilicon layer within trench features and forming a well region, according to an embodiment of the present disclosure;

FIG. 10 is a cross-sectional view of the region of the semiconductor structure after forming an insulating layer and a gate oxide, according to an embodiment of the present disclosure;

FIG. 11 is cross-sectional view of the region of the semiconductor structure after forming metal-oxide-semiconductor transistor source and drain regions and a gate electrode, according to an embodiment of the present disclosure;

FIG. 12 is cross-sectional view of the region of the semiconductor structure after completion of the transistor region, according to an embodiment of the present disclosure; and

FIG. 13 is a flowchart depicting operational steps of a method for forming bonded wafers with epitaxial stacking faults, according to an embodiment of the present disclosure.

The drawings are not necessarily to scale. The drawings are merely schematic representations, not intended to portray specific parameters of the embodiments in the present disclosure. The drawings are intended to depict typical embodiments of the present disclosure. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. The claimed structures and methods may, however, be embodied in many different forms and should not be construed as limited to the exemplary embodiments set forth herein. In the description, details of various conventional features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present disclosure, in the following detailed description, some processing steps or operations that may be ordinary in the art may have been combined together for presentation and for illustration purposes and in some instances may have not been described in detail. In other instances, some processing steps or operations that may be ordinary in the art may not be described at all. It should be understood that the following description is rather focused on the distinctive features or elements of various embodiments of the present disclosure.

Metallic contamination is particularly problematic in bonded wafers because the much thinner device layer can concentrate metallic impurities by up to 100 times compared to non-bonded wafers. In bonded wafer structures, metallic contaminants are confined to the device layer, since they cannot diffuse through the buried oxide layer to the handle wafer, making conventional gettering methods less effective. Traditional gettering techniques, which create crystal damage sites via ion implantation, mechanical damage, polysilicon deposition, or oxygen precipitation, run the risk of allowing these defects to propagate into the active device area, thereby increasing junction leakage and compromising device performance.

Embodiments of the present disclosure provide a solution to the challenge of metallic contamination in bonded wafer technology, providing efficient gettering without compromising device integrity or performance. Specifically, the proposed embodiments introduce a method for metallic gettering in bonded wafer technology that includes growing an epitaxial (epi) layer on top of a device layer that contains engineered epi stacking faults. The stacking faults originate from a point defect at the substrate-epi interface and extend along predetermined crystal planes toward the surface of the epi layer. After wafer bonding, the epi stacking faults are positioned at the bottom of the device layer, directly adjacent to the active region.

The proposed method leverages the stability of epi stacking faults, which are confined to the vicinity of the original point defect and remain unaltered during subsequent high-temperature processing. Unlike traditional gettering methods, the epi stacking faults effectively capture metallic contaminants without the risk of defect propagation into the device area. Additionally, the gettering layer created by these stacking faults exhibits a very low minority carrier lifetime, which can also contribute to preventing complementary metal-oxide-semiconductor (CMOS) latch-up. The process allows for patterning of the gettering regions, enabling targeted contamination control on specific areas of the die. Furthermore, the distinct nature of the stacking faults makes them readily identifiable via cross-sectional defect etch or transmission electron microscopy analysis, providing a means to verify the technology.

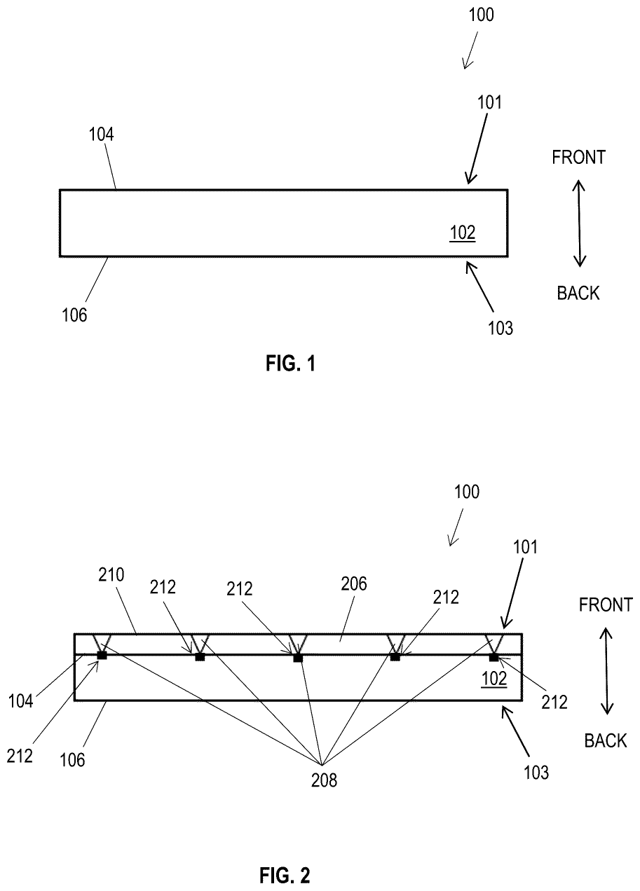

Embodiments by which bonded SOI wafers with epi stacking faults can be formed are described in detail below by referring to the accompanying drawings in FIGS. 1-13.

FIG. 1 is a cross-sectional view of a semiconductor structure 100 at an initial step during a wafer bonding process, according to an embodiment of the present disclosure. At this step, semiconductor structure 100 includes a first wafer (hereinafter “device wafer”) 102 illustrated before performing any processing steps. The device wafer 102 can be a high-purity silicon wafer, selected based on its electrical and mechanical properties to ensure compatibility with subsequent fabrication steps. The device wafer 102 may serve as the foundation for defining buried layers, doped regions, and alignment structures before it is bonded to a handle wafer.

The device wafer 102 includes a first side 101 and a second side 103 opposite to the first side 101. The first side 101 includes a first surface 104, while the second side 103 includes a second surface 106. In an embodiment, the first side 101 corresponds to a front side of the device wafer 102, while the second side 103 corresponds to a back side of the device wafer 102. At this stage of the wafer bonding process, the first surface 104 on the first side 101 of device wafer 102 may be unpatterned and free of oxide or deposited layers, allowing precise control over the initial processing steps. A thickness of the device wafer 102 may typically be chosen based on the final device specifications, considering factors such as dopant diffusion depths, mechanical stability, and post-bonding thinning requirements. The device wafer 102 may be prepared to undergo cleaning and oxidation steps to ensure a contamination-free surface, which is important for achieving high-quality patterning and doping in later steps. In an embodiment, the device wafer 102 may have an initial thickness of approximately 675 μm.

FIG. 2 is a cross-sectional view of the semiconductor structure 100 after forming a first epitaxial layer 206 with stacking faults 208, according to an embodiment of the present disclosure. The description of FIG. 2 may reference components depicted in FIG. 1.

The first epitaxial layer 206 is formed on the first side 101 of device wafer 102. Specifically, the first epitaxial layer 206 is formed above the first surface 104 using a suitable epitaxial growth technique, such as chemical vapor deposition (CVD). The epitaxial growth process aims to maintain the same crystal structure as the underlying device wafer 102 (e.g., a single-crystal silicon substrate).

Stacking faults 208, a type of crystallographic defect, can form within the first epitaxial layer 206 due to point defects 212 at the interface between the device wafer 102 and the first epitaxial layer 206. Point defects 212 often arise from contaminants, surface irregularities, or particles on the wafer, and can propagate upward through the first epitaxial layer 206 along specific crystal planes, typically appearing as square-shaped defects when viewed from above. In the cross-sectional view of FIG. 2, stacking faults 208 exhibit an inverted pyramid or triangular shape with a top portion of each stacking fault 208 pointing toward the second side 103 of the device wafer 102. In the depicted embodiment, the first epitaxial layer 206 including stacking faults 208 is formed on the front side of the semiconductor structure 100.

While standard approaches seek to minimize crystallographic defects such as stacking faults 208 by ensuring a clean and defect-free wafer surface before epitaxial growth, embodiments of the present disclosure intentionally induce stacking faults 208 in the first epitaxial layer 206 while ensuring stacking faults 208 remain confined within the first epitaxial layer 206 and do not extend into the device wafer 102.

To achieve a controlled defect formation, the first surface 104 on the first side 101 undergoes a pre-treatment that promotes the creation of stacking faults 208 during epi growth. Stacking faults 208 may form when the crystal structure of the first surface 104 is locally perturbed or damaged at specific points (i.e., point defects 212). Stated differently, stacking faults 208 can be intentionally created in predefined areas of the device wafer 102 in a controlled manner by pre-damaging (e.g., via ion implantation, laser processing, or selective oxidation) localized regions of the first surface 104 to form point defects 212 prior to epitaxial growth. These localized regions may act as nucleation sites for stacking fault formation, ensuring they appear in specific areas where they can be used for contamination trapping or other beneficial purposes.

Various pre-treatment techniques may be employed to perturb or damage the first surface 104. For example, formation of stacking faults 208 may include patterned stacking faults or unpatterned stacking faults. In the patterned approach, a masking layer (not shown) is deposited and patterned on the device wafer 102 to selectively expose areas for stacking fault pre-treatment. The masking layer's material composition and patterning process depend on the pre-treatment technique used. Once the pre-treatment is complete, the masking layer is removed before depositing the first epitaxial layer 206. In the unpatterned approach, stacking faults 208 may arise spontaneously due to crystal imperfections, growth conditions, or induced stress during epitaxial deposition.

Following the pre-treatment step, the first epitaxial layer 206 can be epitaxially grown above the first surface 104 of device wafer 102. The stacking faults 208 originate at point defects 212 located at an interface between the first epitaxial layer 206 and the device wafer 102 and propagate upward through the first epitaxial layer 206 but do not extend downward into the device wafer 102, as illustrated in FIG. 2. A thickness, resistivity, and dopant type of the first epitaxial layer 206 can be tuned based on design requirements. For example, the first epitaxial layer 206 may have a dopant type and resistivity that match the device wafer 102, making it an extension of the device wafer 102. Alternatively, the first epitaxial layer 206 can be heavily doped to function as a buried layer or left undoped.

Once the first epitaxial layer 206 is formed, an upper surface 210 of the semiconductor structure 100 is polished to remove any crystal facets caused by stacking faults 208 that may extend above the upper surface 210. This polishing step may ensure a smooth upper surface 210 suitable for subsequent wafer bonding. While some portions of the first epitaxial layer 206 may be removed during the polishing step, the first epitaxial layer 206 remains sufficiently intact to preserve its intended function in the final structure.

In an embodiment, a thickness of the first epitaxial layer 206 and a density (number of defects per unit area) of stacking faults 208 can be controlled and may be adjusted based on design requirements, ensuring that the stacking faults 208 remain confined to a non-critical region without impacting device performance. In an exemplary embodiment, the first epitaxial layer 206 may have a thickness varying from approximately 2 μm to approximately 10 μm.

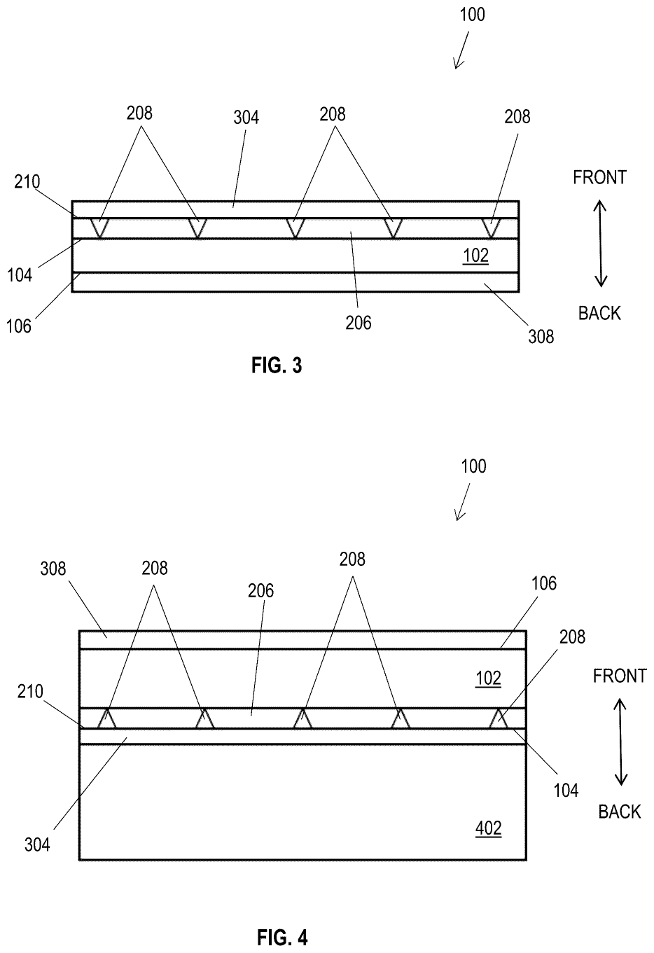

FIG. 3 is a cross-sectional view of the semiconductor structure 100 after forming a first oxide layer 304 and a second oxide layer 308, according to an embodiment of the present disclosure. The description of FIG. 3 may reference components depicted in FIGS. 1-2.

After polishing and wafer cleaning, the first oxide layer 304 is formed above the upper surface 210 of the first epitaxial layer 206, while the second oxide layer 308 is formed on the second surface 106 of device wafer 102. For example, the first oxide layer 304 can be thermally grown or deposited on the upper surface 210 of the first epitaxial layer 206. Similarly, the second oxide layer 308 can be thermally grown or deposited on the second surface 106 of device wafer 102.

In one embodiment, the first oxide layer 304 and the second oxide layer 308 may be composed of silicon dioxide (SiO₂) and have a thickness varying from approximately 0.5 μm to approximately 1.2 μm. In some cases, the formation of the first oxide layer 304 and the second oxide layer 308 may result in the consumption of a portion of the first epitaxial layer 206. This material loss needs to be considered when determining the appropriate thickness of the first epitaxial layer 206 to be deposited.

FIG. 4 is a cross-sectional view of the semiconductor structure 100 after bonding the device wafer 102 to a second wafer (hereinafter “handle wafer”) 402 and flipping the device wafer 102, according to an embodiment of the present disclosure. The description of FIG. 4 may reference components depicted in FIGS. 1-3.

At this stage, the device wafer 102 is bonded to the handle wafer 402, which provides mechanical support and structural stability for subsequent processing steps. The first oxide layer 304 on the upper surface 210 of the first epitaxial layer 206 may facilitate oxide-to-oxide wafer bonding, ensuring a strong adhesion between the device wafer 102 and the handle wafer 402.

In one or more embodiments, the bonding process can be performed using wafer direct bonding or adhesive bonding techniques. In the case of direct bonding, the wafers are precisely aligned and brought into contact, allowing intermolecular forces to create an initial bond. A subsequent annealing step at elevated temperatures strengthens the bond by promoting chemical reactions between oxide surfaces, forming a stable silicon dioxide (SiO₂) interface.

After bonding the device wafer 102 to the handle wafer 402, the device wafer 102 is flipped, as shown in FIG. 4. Once flipped, the first surface 104 of the device wafer 102 is positioned at the back side of the semiconductor structure 100, while the second surface 106, with the second oxide layer 308 above it, is positioned at the front side of the semiconductor structure 100. This reorientation may ensure that a subsequent thinning process is performed on the original back side (i.e., second side 103) of the device wafer 102, which will serve as the active device layer for subsequent processing.

The second oxide layer 308 may act as a masking layer, selectively protecting areas of device wafer 102 during subsequent processing steps. Second oxide layer 308 would be removed during a subsequent grinding process.

After flipping the device wafer 102, the first epitaxial layer 206 containing stacking faults 208 is now positioned at the back side of the semiconductor structure 100, as shown in FIG. 4. At this stage, the device wafer 102 may be ground and polished to achieve a desired thickness. Specifically, a thinning process can be conducted on the back side (e.g., second side 103 depicted in FIG. 1) of the device wafer 102 to achieve the required final device layer thickness. In an embodiment, the thinning process may begin with mechanical grinding, where a high-precision grinding tool removes excess silicon from the exposed surface of the device wafer 102. This initial grinding step may rapidly reduce the wafer thickness but may introduce surface roughness or subsurface damage. To refine the surface and achieve the desired final thickness, a chemical mechanical polishing (CMP) step is subsequently performed. CMP utilizes a combination of chemical etching and mechanical abrasion to create a highly planar surface with minimal defects.

A portion of the device wafer 102 remains after these processes to ensure a defect-free layer for device formation. The remaining device wafer 102 above the first epitaxial layer 206 may be sufficiently thick to prevent electrical depletion regions from reaching the stacking faults 208. The stacking faults 208 at the back side of the semiconductor structure 100 may help attract and trap metallic contaminants, preventing them from reaching active devices, where they may otherwise cause junction leakage and oxide integrity issues.

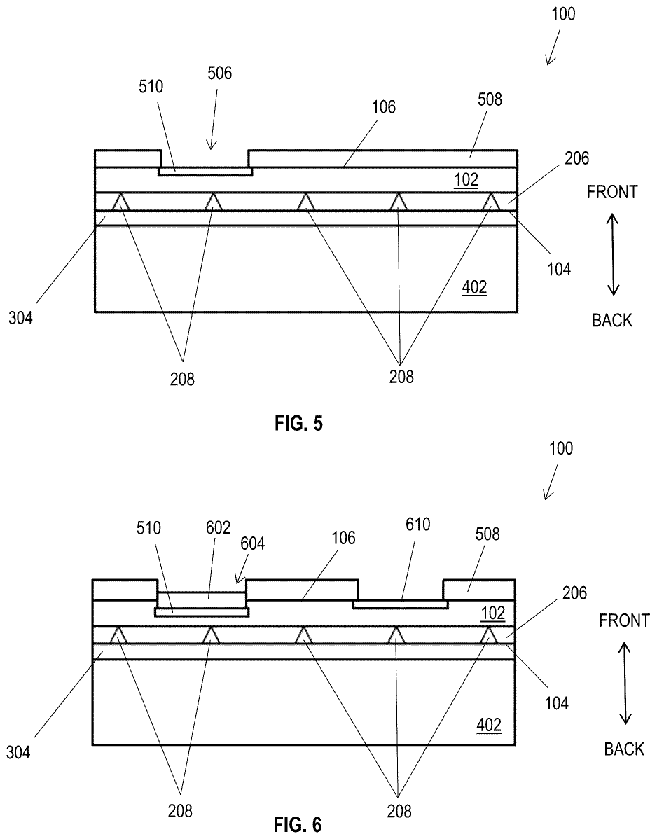

FIG. 5 is a cross-sectional view of the semiconductor structure 100 after grinding and polishing the device wafer 102 to a final thickness and forming a first buried layer 510 within the device wafer 102, according to an embodiment of the present disclosure. The description of FIG. 5 may reference components depicted in FIGS. 1-4.

A third oxide layer 508 is grown or deposited on the device wafer 102, then a photolithography process is conducted on the third oxide layer 508 to define a pattern for the first buried layer 510. In this process a photoresist layer (not shown) is applied to a surface of the third oxide layer 508 and patterned using an exposure mask (not shown) that defines a location of the first buried layer 510. After development, exposed portions of the third oxide layer 508 can be etched, creating an opening 506 in the third oxide layer 508 where doping will be introduced to form first buried layer 510.

The process continues by conducting an ion implantation process or a thermal diffusion process on the device wafer 102 to form first buried layer 510. According to an embodiment, first buried layer 510 is an N-type buried layer (NBL). In embodiments in which dopant introduction is achieved by ion implantation, N-type dopant atoms (e.g., phosphorus or arsenic) are accelerated into silicon regions exposed by the opening 506 at controlled energy levels, embedding them at a precise depth. In embodiments in which dopant introduction is achieved by thermal diffusion, a dopant source is introduced, and high temperatures drive the diffusion of N-type atoms into the silicon through the opening 506 to form the first buried layer 510. The third oxide layer 508 may act as a mask for controlling where the N-type dopants can be introduced while protecting other regions from unwanted doping.

In one or more embodiments, after doping, device wafer 102 may undergo a high-temperature annealing process to activate N-type dopants, allowing them to fully integrate into the silicon lattice while repairing any crystal damage caused by implantation.

FIG. 6 is a cross-sectional view of the semiconductor structure 100 after oxidizing the first buried layer 510 and forming a second buried layer 610 within the device wafer 102, according to an embodiment of the present disclosure. The description of FIG. 6 may reference components depicted in FIGS. 1-5.

After the formation of first buried layer 510, the device wafer 102 may undergo a thermal oxidation process, where exposed silicon in the first buried layer 510 can be oxidized to form a protective oxide layer or fourth oxide layer 602 above the first buried layer 510. The fourth oxide layer 602 may prevent unwanted doping in the first buried layer 510, provide electrical isolation, and establish a stable surface for subsequent processing steps. In the example of FIG. 6, the fourth oxide layer 602 may be composed of SiO₂ and have a thickness varying from approximately 0.5 μm to approximately 1.0 μm.

Formation of the fourth oxide layer 602 creates a step 604 in the second surface 106 of the device wafer 102. The step 604 may serve as a topographical alignment mark for subsequent photolithography steps, ensuring accurate positioning of future mask levels on this side (front-side) of the device wafer 102. A depth and profile of the step 604 may be controlled to maintain precision in alignment while preserving the integrity of the underlying silicon layer.

Following the oxidation process and alignment mark formation, a photolithography step can be performed on the device wafer 102 to define the second buried layer 610. In an embodiment, the second buried layer 610 is a P-type buried layer (PBL). A photoresist layer (not shown) can be applied over the oxidized device wafer 102 and selectively exposed, using a mask (not shown), a location of the second buried layer 610. After development, the exposed oxide regions can be etched, revealing the underlying silicon where P-type dopants can be introduced to form the second buried layer 610.

With the second buried layer 610 defined, the device wafer 102 may undergo P-type doping using ion implantation or thermal diffusion. P-type dopants such as boron (B) can be introduced into the exposed silicon regions to form the second buried layer 610. After implantation or diffusion, a high-temperature annealing process can be conducted on the device wafer 102 to activate the P-type dopants and allow them to fully integrate into the silicon lattice.

At the completion of this step, the device wafer 102 includes fully formed N-type and P-type buried layers (first and second buried layers 510, 610). The first and second buried layers 510, 610 may establish electrical pathways and pattern features that will be utilized in the subsequent fabrication steps, including patterning and etching of trench features for additional electrical isolation and alignment.

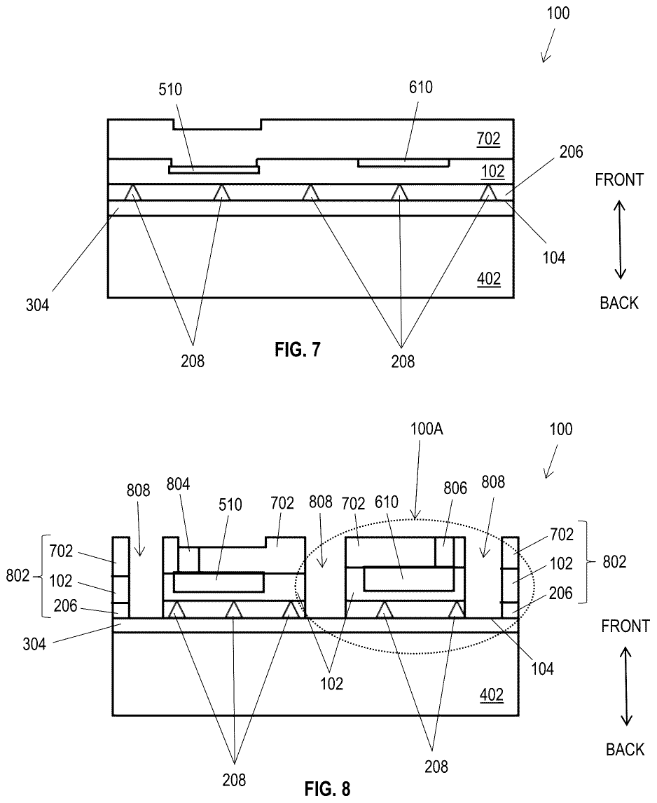

FIG. 7 is a cross-sectional view of the semiconductor structure 100 after forming a second epitaxial layer 702 above the device wafer 102, according to an embodiment of the present disclosure. The description of FIG. 7 may reference components depicted in FIGS. 1-6.

Following the formation of the first buried layer 510 (NBL) and second buried layer 610 (PBL), the second epitaxial layer 702 can be formed above the device wafer 102. The second epitaxial layer 702 serves as active region for subsequent device fabrication. Before forming the second epitaxial layer 702, the third oxide layer 508 and fourth oxide layer 602 can be selectively removed from the semiconductor structure 100 (e.g., using a wet etch process with hydrofluoric acid (HF)) to expose the underlying silicon surface for proper epitaxial growth.

In one or more embodiments, the second epitaxial layer 702 may be grown using a CVD process, ensuring precise control over thickness, doping concentration, and material composition. The doping profile of the second epitaxial layer 702 can be tailored to achieve the desired electrical properties and compatibility with the underlying buried layers. A thickness of the second epitaxial layer 702 may vary between approximately 5 μm to approximately 10 μm. At this stage, a combined thickness of the device wafer 102 and second epitaxial layer 702 may vary between approximately 10 μm to approximately 15 μm.

FIG. 8 is a cross-sectional view of the semiconductor structure 100 after forming a first sinker region 804 and a second sinker region 806, and etching trench features 808, according to an embodiment of the present disclosure. The description of FIG. 7 may reference components depicted in FIGS. 1-6.

First sinker region 804 and second sinker region 806 can be formed within the second epitaxial layer 702, positioned above the device wafer 102. First sinker region 804 and second sinker region 806 are heavily doped regions that provide a low-resistance electrical path between surface contacts and the first buried layer 510 and the second buried layer 610, respectively. First sinker region 804 and second sinker region 806 may ensure electrical connectivity between different device regions.

The process of forming the first sinker region 804 and the second sinker region 806 typically includes a photolithography step in which sinker regions are defined within the second epitaxial layer 702. This is followed by an ion implantation or thermal diffusion step using either N-type (e.g., phosphorus or arsenic) or P-type dopants (e.g., boron), depending on device design. A subsequent annealing step at high temperatures drives the dopants deeper into the second epitaxial layer 702, ensuring that the first sinker region 804 and second sinker region 806 extend down to the first buried layer 510 and second buried layer 610 for proper electrical contact. In this embodiment, the first sinker region 804 includes an N-type doped region (N-type sinker) and the second sinker region 806 includes a P-type doped region (P-type sinker).

After forming the first sinker region 804 and second sinker region 806, trench features 808 can be patterned and etched into the second epitaxial layer 702 and device wafer 102. As shown in FIG. 8, trench features 808 may extend into the first epitaxial layer 206 until an uppermost surface of the first oxide layer 304 is exposed.

For easy of illustration, without intent of limitation, the second epitaxial layer 702, device wafer 102, and first epitaxial layer 206 will collectively be referred to as “device layer” 802 in the description of the following embodiments.

A photolithography process is first performed to define the trench locations. A photoresist layer (not shown) is applied to the surface of the device layer 802 and selectively exposed using a mask (not shown) that outlines the trench structures. After development, exposed regions of the device layer 802 can be etched to form trench features 808. In an embodiment, trench etching can be conducted using, for example, a deep reactive ion etching (DRIE) or another anisotropic etching technique, ensuring precise vertical trench walls and controlled depths. A depth of the trench features 808 is the same as the final thickness of the device layer 802.

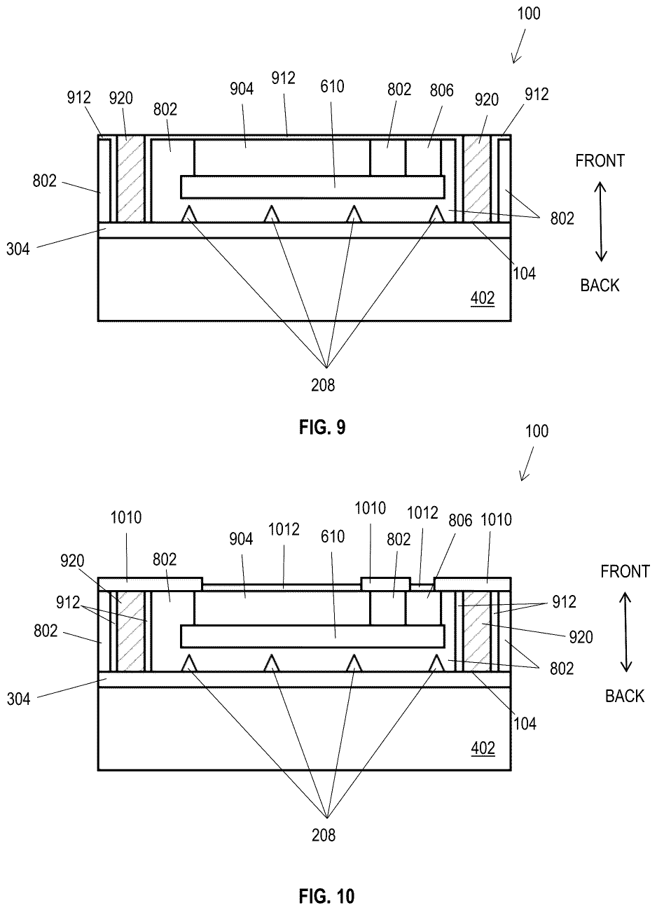

FIG. 9 is a cross-sectional view of a region 100A of the semiconductor structure 100, as depicted in FIG. 8, after forming a polysilicon layer 920 within trench features 808 and forming a well region 904, according to an embodiment of the present disclosure. The description of FIG. 9 may reference components depicted in FIGS. 1-8.

For ease of illustration, without intent of limitation, the following embodiments will be described with reference to the region 100A depicted in FIG. 8. It may be understood that similar processes are conducted in remaining areas of the semiconductor structure 100.

After forming trench features 808 within device layer 802, an oxidation process can be performed on the semiconductor structure 100 to grow a thin oxide layer (hereinafter “fifth oxide layer”) 912 on exposed silicon surfaces. The fifth oxide layer 912 is formed along sidewalls of trench features 808, with a bottom surface of trench features 808 being covered by the first oxide layer 304, as depicted in the figure. The fifth oxide layer 912 may also grow on an uppermost surface of the semiconductor structure 100.

The fifth oxide layer 912 may be composed of SiO₂ and have a thickness varying from approximately 0.1 μm to approximately 0.3 μm. During the oxidation step, the fifth oxide layer 912 extends to and interfaces with previously formed oxide layers, including first oxide layer 304, ensuring a continuous insulating structure across the semiconductor surface. The oxidation process may help passivate the exposed silicon surfaces, reducing surface defects and preventing unwanted dopant diffusion. The fifth oxide layer 912 may also enhance electrical isolation between adjacent active regions, ensuring optimal device performance.

After the oxidation step, trench features 808 can be filled with a polysilicon (poly-Si) layer 920. In an embodiment, the polysilicon layer 920 can be deposited using a low-pressure chemical vapor deposition (LPCVD) process, ensuring uniform trench filling with high-purity material. Following the deposition of the polysilicon layer 920, an etch-back or chemical mechanical polishing (CMP) process can be performed on the semiconductor structure 100 to remove excess polysilicon material and achieve a flat, planarized surface. This step ensures that upper surfaces of the semiconductor structure 100 are leveled, allowing for precise patterning and processing in subsequent fabrication steps.

In the depicted embodiment, well region 904 is formed above the second buried layer 610 (PBL) using ion implantation and thermal diffusion. In an embodiment, the well region 904 can be a P-type doped well region configured to provide a localized region of P-type doping within the region 100A. Well region 904 may help defining active device regions in the semiconductor structure 100.

The process of forming the well region 904 starts with ion implantation. In embodiments in which the well region 904 is a P-type well region, boron (B) or other P-type dopants are introduced into exposed silicon surfaces using a high-energy ion beam. The implantation dose and energy can be controlled to achieve the desired doping concentration and depth. This ensures that the well region 904 extends sufficiently into the silicon to form a stable and well-defined electrical region.

Following implantation, a thermal diffusion process can be performed on the device layer 802, where high-temperature annealing allows the implanted dopants to migrate deeper into the silicon lattice. The thermal diffusion process may provide a gradual dopant profile in the well region 904, reducing abrupt junction transitions and improving device performance. In an embodiment, well region 904 is aligned with the second buried layer 610 (PBL). This alignment may maintain proper electrical continuity and isolation from adjacent structures.

FIG. 10 is a cross-sectional view of the region 100A of the semiconductor structure 100, as depicted in FIG. 8, after forming an insulating layer 1010 and a gate oxide 1012, according to an embodiment of the present disclosure. The description of FIG. 10 may reference components depicted in FIGS. 1-9.

Prior to forming the insulating layer 1010 and gate oxide 1012, portions of the fifth oxide layer 912 positioned above the uppermost surface of the device layer 802 can be selectively removed from the semiconductor structure 100 using, for example, a hydrofluoric acid (HF) etching to expose upper surfaces of the device layer 802. For simplicity of illustration, following removal of the fifth oxide layer 912, the upper surface of the device layer 802 is depicted as being coplanar with the upper surface of the polysilicon layer 920. However, in practice, the upper surface of the trench-filled polysilicon layer 920 may be at a different height relative to the device layer 802.

A thermal oxidation process can be performed on the semiconductor structure 100 to form the insulating layer 1010 on the exposed silicon regions of device layer 802. In one or more embodiments, the insulating layer 1010, which may also be referred to as field oxide, serves as an isolation barrier for preventing electrical interference between adjacent active devices. A thickness of the insulating layer 1010 can be controlled to achieve optimal electrical isolation while maintaining compatibility with later processing steps. In an exemplary embodiment, the thickness of the insulating layer 1010 may be approximately 0.6 μm.

Gate oxide 1012 can be grown over the exposed silicon regions through thermal oxidation. The gate oxide 1012 may serve as an insulating layer between a subsequently formed gate electrode and underlying channel region (not shown), ensuring proper electrical operation. In an embodiment, a thickness of the gate oxide 1012 may vary between approximately 0.01 μm and approximately 0.05 μm.

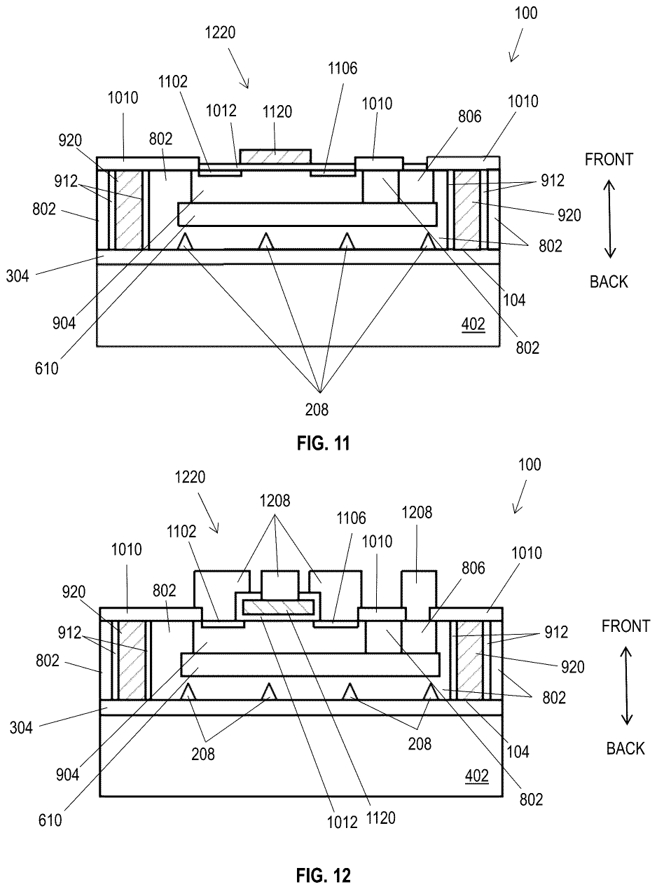

FIGS. 11-12 are cross-sectional views of the region 100A of the semiconductor structure 100, as depicted in FIG. 8, depicting forming metal-oxide-semiconductor (MOS) transistor source and drain regions 1102, 1106 and gate electrode 1120, according to an embodiment of the present disclosure. The description of FIGS. 11-12 may reference components depicted in FIGS. 1-10.

Following the formation of the gate oxide 1012, a polysilicon layer is deposited and patterned to define gate electrode 1120. The polysilicon layer can be deposited over the entire wafer surface using, for example, low-pressure chemical vapor deposition (LPCVD). The polysilicon layer can be doped in-situ during deposition or after deposition through an implant or furnace deposition and drive in process. A photolithography step is then performed to define the gate electrode 1120, followed by etching to remove excess polysilicon, leaving behind the patterned gate electrode 1120 in the active regions of device layer 802, as illustrated in FIG. 11.

An oxidation process can be performed on the semiconductor structure 100 to oxidize the gate electrode 1120. During the oxidation process, a thin oxide layer can be formed on the polysilicon surface. For ease of illustration the thin oxide layer formed around the gate electrode 1120 is collectively depicted with the gate oxide 1012, as shown in FIG. 12. This oxidation step may improve the stability of the gate electrode 1120, provides passivation, and helps reduce gate-to-contact leakage in subsequent metallization steps.

Following the oxidation process, source and drain doping can be performed to introduce highly conductive regions into the well region 904. In an embodiment, this step may involve implanting N-type dopants (such as phosphorus or arsenic) into the exposed silicon regions adjacent to the gate electrode 1120 to form source region 1102 and drain region 1106. The doping parameters, including dose and energy, can be controlled to ensure proper junction depth and electrical characteristics, optimizing the transistor's performance.

After forming the source region 1102 and the drain region 1106, a contact etching process can be conducted to create openings (not shown) through insulating layers, exposing source, drain and body contact regions. A photolithography step defines the contact locations, followed by anisotropic etching, which ensures that the contact openings extend precisely to the underlying silicon. The etched contacts allow direct electrical connections to the transistor's active regions.

Finally, a metal layer 1208 is deposited over the surface of device layer 802 using, for example, physical vapor deposition (PVD) or sputtering techniques. The metal layer 1208 serves as the electrical interconnects for the transistor. A photolithography and etching process is then performed to pattern the metal layer 1208 such that it connects the source region 1102, the drain region 1106, the gate electrode 1120, and second sinker region 806 (body region) as required for circuit functionality. The metal layer 1208 establishes low-resistance pathways for external connections, completing fabrication of MOS transistor region 1220. It should be noted that although the cross-sectional views of FIGS. 11-12 depict the transistor region 1220 as being positioned between two adjacent trench features 808 filled with the polysilicon layer 920, in practical implementations the polysilicon-filled trench features 808 may surround the transistor region on all sides to provide electrical isolation from adjacent devices or circuits.

Embodiments of the present disclosure provide a semiconductor structure 100 in which stacking faults 208 formed within the first epitaxial layer 206, and located beneath the second buried layer 610, may serve as traps for metallic contaminants. As mentioned above, metallic contaminants can accumulate on the device wafer due to various semiconductor fabrication steps such as etching, photolithography, and furnace cycles. When exposed to high temperatures, these contaminants diffuse into the silicon, potentially leading to junction leakage, oxide integrity degradation, and overall device reliability issues. As metallic impurities diffuse through the device wafer 102, they migrate toward the stacking faults 208 due to a concentration gradient, where they become permanently trapped. This mechanism can draw contamination away from the active transistor regions, ensuring a cleaner and more stable silicon structure. By leveraging stacking faults 208 as contamination sinks, the proposed method can improve device performance and long-term reliability.

Furthermore, stacking faults 208 can be strategically confined within the first epitaxial layer 206, avoiding propagation into the active device wafer 102. The size and density of stacking faults 208 can be controlled, ensuring they remain localized below the second buried layer 610 without extending into the MOS transistor region 1220, where they may otherwise degrade performance. This defect isolation approach may prevent device failure caused by structural instability or electronic defects. By maintaining the stacking faults 208 away from active device areas, the proposed method may allow for higher fabrication yields, improved transistor reliability, and enhanced semiconductor device performance.

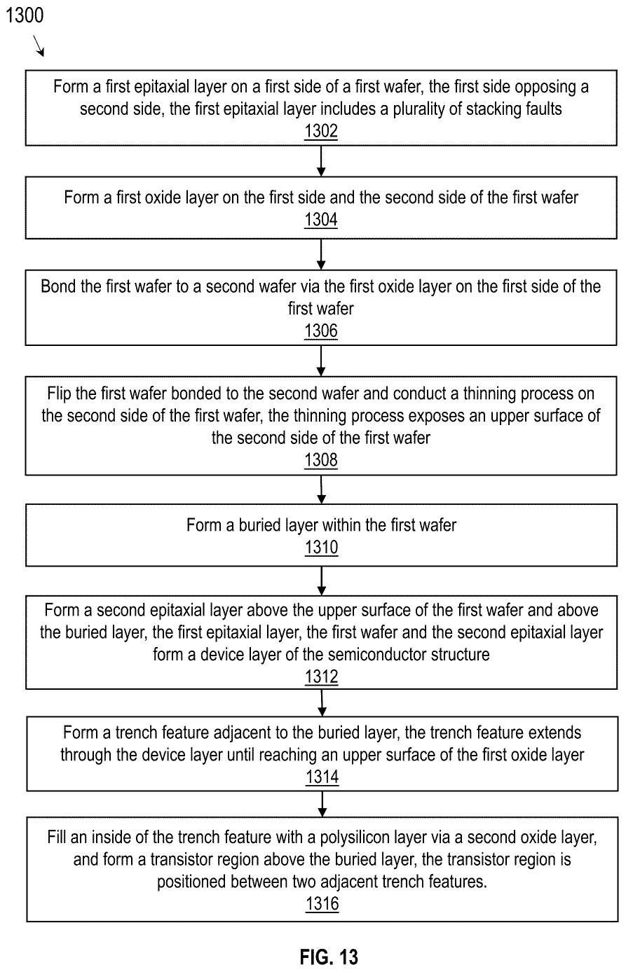

FIG. 13 is a flowchart 1300 depicting operational steps of a method for forming bonded wafers with epitaxial stacking faults, according to an embodiment of the present disclosure.

The process starts at step 1302 by forming a first epitaxial layer on a first side of a first wafer, with the first side opposing a second side. The first epitaxial layer includes a plurality of stacking faults. In one or more embodiments, forming the first epitaxial layer having the plurality of stacking faults further includes conducting a pre-treatment on the first side of the first wafer, with the pre-treatment locally damaging a surface of the first wafer at predetermined areas to create point defects at an interface between the first epitaxial layer and the first side of the first wafer, epitaxially growing the first epitaxial layer, with the plurality of stacking faults forming at the point defects and propagating upward through the first epitaxial layer, and polishing an upper surface of the first epitaxial layer. In one or more embodiments, the plurality of stacking faults within the first epitaxial layer has a triangular or square shape, with a top portion of each of the plurality of stacking faults pointing toward the second side of the first wafer. In one or more embodiments, the conducted pre-treatment includes at least one of a patterned approach or an unpatterned approach for forming the plurality of stacking faults.

The process continues at step 1304 by forming a first oxide layer on the first side and the second side of the first wafer. At step 1306 the first wafer is bonded to a second wafer via the first oxide layer on the first side of the first wafer. In one or more embodiment, the first wafer is a device wafer and the second wafer is a handle wafer. At step 1308 the first wafer bonded to the second wafer is flipped and a thinning process is conducted on the second side of the first wafer, with the thinning process exposing an upper surface of the second side of the first wafer.

The process continues at step 1310 by forming a buried layer within the first wafer, above the first epitaxial layer. At step 1312 a second epitaxial layer is formed above the upper surface of the first wafer and above the buried layer. In an embodiment, the first epitaxial layer, the first wafer and the second epitaxial layer form a device layer of the semiconductor structure. At step 1314 a trench feature is formed adjacent to the buried layer, the trench feature extends through the device layer until reaching an upper surface of the first oxide layer.

Finally, at step 1316, an inside of the trench feature is filled with a polysilicon layer via a second oxide layer, anda transistor region is formed above the buried layer. In one or more embodiments, forming the transistor region further includes forming a sinker region within the second epitaxial layer in alignment with the buried layer, forming a well region above the buried layer, forming an insulating layer above the trench feature, the insulating layer partially extending above the buried layer and the sinker region, forming a gate oxide over the well region, forming a gate electrode over the gate oxide, oxidizing the gate electrode, forming a source region and a drain region on opposite sides of the gate electrode, and forming a metal contact to the source region, the gate electrode, the drain region, and the sinker region.

### Examples

Example 1. A method of forming a semiconductor structure, the method comprising:
   forming a first epitaxial layer on a first side of a first wafer, the first side opposing a second side,
   wherein the first epitaxial layer includes a plurality of stacking faults;
   forming a first oxide layer on the first side of the first wafer and on the second side of the first wafer;
   bonding the first wafer to a second wafer via the first oxide layer on the first side of the first wafer;
   flipping the first wafer bonded to the second wafer;
   conducting a thinning process on the second side of the first wafer, the thinning process exposing an upper surface of the second side of the first wafer;
   forming a buried layer within the first wafer;
   forming a second epitaxial layer above the upper surface of the first wafer and above the buried layer,
   wherein the first epitaxial layer, the first wafer and the second epitaxial layer form a device layer of the semiconductor structure;
   forming a trench feature adjacent to the buried layer, the trench feature extending through the device layer until reaching an upper surface of the first oxide layer;
   filling an inside of the trench feature with a polysilicon layer via a second oxide layer; and
   forming a transistor region above the buried layer.
Example 2. The method according to Example 1, wherein forming the first epitaxial layer further comprises:
   conducting a pre-treatment on the first side of the first wafer,
   wherein the pre-treatment locally damages the first wafer at predetermined areas to create point defects at an interface between the first epitaxial layer and the first side of the first wafer;
   epitaxially growing the first epitaxial layer,
   wherein the plurality of stacking faults form at the point defects and propagate upward through the first epitaxial layer; and
   polishing an upper surface of the first epitaxial layer.
Example 3. The method according to Example 1, wherein the plurality of stacking faults within the first epitaxial layer has at least one of a triangular shape or a square shape, each of the plurality of stacking faults pointing toward the second side of the first wafer.
Example 4. The method according to claim 2, wherein the pre-treatment includes at least one of a patterned approach or an unpatterned approach for forming the plurality of stacking faults.
Example 5. The method according to Example 1, wherein the first wafer is a device wafer and the second wafer is a handle wafer.
Example 6. The method according to Example 1, wherein forming the transistor region further comprises:
   forming a sinker region within the second epitaxial layer in alignment with the buried layer.
Example 7. The method according to Example 6, wherein forming the transistor region further comprises:
   forming a well region above the buried layer, and
   forming an insulating layer above the trench feature, the insulating layer partially extending above the buried layer and the sinker region.
Example 8. The method according to Example 7, wherein forming the transistor region further comprises:
   forming a gate oxide over the well region;
   forming a gate electrode over the gate oxide;
   oxidizing the gate electrode;
   forming a source region and a drain region in the well region, the source region and the drain region being on opposite sides of the gate electrode; and
   forming a metal contact to the source region, the gate electrode, the drain region, and the sinker region.
Example 9. A method of forming a semiconductor structure, the method comprising:
   forming point defects at predefined areas of a first side of a first wafer, the first wafer having a second side opposing the first side;
   epitaxially growing a first epitaxial layer on the first side of the first wafer,
   wherein a stacking fault is formed at each point defect located at an interface between the first wafer and the first epitaxial layer, the stacking fault propagating upward through the first epitaxial layer;
   forming a first oxide layer on the first side of the first wafer and on the second side of the first wafer;
   bonding the first wafer to a second wafer via the first oxide layer on the first side of the first wafer;
   flipping the first wafer bonded to the second wafer;
   conducting a thinning process on the second side of the first wafer, the thinning process exposing an upper surface of the second side of the first wafer;
   forming a buried layer within the first wafer;
   forming a second epitaxial layer above the upper surface of the first wafer and above the buried layer,
   wherein the first epitaxial layer, the first wafer and the second epitaxial layer form a device layer;
   forming a trench feature adjacent to the buried layer, the trench feature extending through the device layer until reaching an upper surface of the first oxide layer;
   filling an inside of the trench feature with a polysilicon layer via a second oxide layer; and
   forming a transistor region above the buried layer.
Example 10. The method according to Example 9, wherein the stacking fault within the first epitaxial layer has at least one of a triangular shape or a square shape, the stacking fault pointing toward the second side of the first wafer.
Example 11. The method according to Example 9, wherein forming the point defects further comprises:
   conducting a pre-treatment on the first side of the first wafer using at least one of a patterned approach or an unpatterned approach.
Example 12. The method according to Example 9, wherein the first wafer is a device wafer and the second wafer is a handle wafer.
Example 13. The method according to Example 9, wherein forming the transistor region further comprises:
   forming a sinker region within the second epitaxial layer in alignment with the buried layer.
Example 14. The method according to Example 13, wherein forming the transistor region further comprises:
   forming a well region above the buried layer, and
   forming an insulating layer above the trench feature, the insulating layer partially extending above the buried layer and the sinker region.
Example 15. The method according to Example 14, wherein forming the transistor region further comprises:
   forming a gate oxide over the well region;
   forming a gate electrode over the gate oxide;
   oxidizing the gate electrode;
   forming a source region and a drain region in the well region, the source region and the drain region being on opposite sides of the gate electrode; and
   forming a metal contact to the source region, the gate electrode, the drain region, and the sinker region.
Example 16. A semiconductor structure comprising:
   a first wafer including a device layer on a first side, the first wafer having a second side opposing the first side,
   wherein the device layer includes:
   a plurality of stacking faults positioned on a bottom portion of the device layer,
   a buried layer positioned within the device layer above the plurality of stacking faults, and
   a transistor region electrically connected to the buried layer; and
   a second wafer bonded to the first side of the first wafer via a first oxide layer.
Example 17. The semiconductor structure according to Example 16, further comprising:
   a trench feature adjacent to the transistor region, the buried layer, and the plurality of stacking faults; and
   a polysilicon layer located within the trench feature.
Example 18. The semiconductor structure according to Example 16, wherein the device layer further comprises:
   a first epitaxial layer positioned above the first oxide layer; and
   a second epitaxial layer positioned above the buried layer.
Example 19. The semiconductor structure according to Example 18, wherein each of the plurality of stacking faults is positioned at a point defect at an interface between the first wafer and the first epitaxial layer, the plurality of stacking faults propagates upward through the first epitaxial layer.
Example 20. The semiconductor structure according to Example 18, wherein the plurality of stacking faults has at least one of a square shape or triangular shape, each of the plurality of stacking faults pointing toward the first side of the first wafer.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Spatially relative terms, such as “inner,” “outer,” “beneath,” “below,” “lower,” “above,” “upper,” “top,” “bottom,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” may encompass both an orientation of above and below. The device may be otherwise oriented (rotated 90 degrees or at other orientations) and the spatially relative descriptors used herein interpreted accordingly.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method of forming a semiconductor structure, the method comprising:
forming a first epitaxial layer on a first side of a first wafer, the first side opposing a second side,
wherein the first epitaxial layer includes a plurality of stacking faults;
forming a first oxide layer on the first side of the first wafer and on the second side of the first wafer;
bonding the first wafer to a second wafer via the first oxide layer on the first side of the first wafer;
flipping the first wafer bonded to the second wafer;
conducting a thinning process on the second side of the first wafer, the thinning process exposing an upper surface of the second side of the first wafer;
forming a buried layer within the first wafer;
forming a second epitaxial layer above the upper surface of the first wafer and above the buried layer,
wherein the first epitaxial layer, the first wafer and the second epitaxial layer form a device layer of the semiconductor structure;
forming a trench feature adjacent to the buried layer, the trench feature extending through the device layer until reaching an upper surface of the first oxide layer;
filling an inside of the trench feature with a polysilicon layer via a second oxide layer; and
forming a transistor region above the buried layer.

2. The method according to claim 1, wherein forming the first epitaxial layer further comprises:
conducting a pre-treatment on the first side of the first wafer,
wherein the pre-treatment locally damages the first wafer at predetermined areas to create point defects at an interface between the first epitaxial layer and the first side of the first wafer;
epitaxially growing the first epitaxial layer,
wherein the plurality of stacking faults form at the point defects and propagate upward through the first epitaxial layer; and
polishing an upper surface of the first epitaxial layer.

3. The method according to claim 1, wherein the plurality of stacking faults within the first epitaxial layer has at least one of a triangular shape or a square shape, each of the plurality of stacking faults pointing toward the second side of the first wafer.

4. The method according to claim 2, wherein the pre-treatment includes at least one of a patterned approach or an unpatterned approach for forming the plurality of stacking faults.

5. The method according to claim 1, wherein the first wafer is a device wafer and the second wafer is a handle wafer.

6. The method according to claim 1, wherein forming the transistor region further comprises:
forming a sinker region within the second epitaxial layer in alignment with the buried layer.

7. The method according to claim 6, wherein forming the transistor region further comprises:
forming a well region above the buried layer, and
forming an insulating layer above the trench feature, the insulating layer partially extending above the buried layer and the sinker region.

8. The method according to claim 7, wherein forming the transistor region further comprises:
forming a gate oxide over the well region;
forming a gate electrode over the gate oxide;
oxidizing the gate electrode;
forming a source region and a drain region in the well region, the source region and the drain region being on opposite sides of the gate electrode; and
forming a metal contact to the source region, the gate electrode, the drain region, and the sinker region.

9. A method of forming a semiconductor structure, the method comprising:
forming point defects at predefined areas of a first side of a first wafer, the first wafer having a second side opposing the first side;
epitaxially growing a first epitaxial layer on the first side of the first wafer,
wherein a stacking fault is formed at each point defect located at an interface between the first wafer and the first epitaxial layer, the stacking fault propagating upward through the first epitaxial layer;
forming a first oxide layer on the first side of the first wafer and on the second side of the first wafer;
bonding the first wafer to a second wafer via the first oxide layer on the first side of the first wafer;
flipping the first wafer bonded to the second wafer;
conducting a thinning process on the second side of the first wafer, the thinning process exposing an upper surface of the second side of the first wafer;
forming a buried layer within the first wafer;
forming a second epitaxial layer above the upper surface of the first wafer and above the buried layer,
wherein the first epitaxial layer, the first wafer and the second epitaxial layer form a device layer;
forming a trench feature adjacent to the buried layer, the trench feature extending through the device layer until reaching an upper surface of the first oxide layer;
filling an inside of the trench feature with a polysilicon layer via a second oxide layer; and
forming a transistor region above the buried layer.

10. The method according to claim 9, wherein the stacking fault within the first epitaxial layer has at least one of a triangular shape or a square shape, the stacking fault pointing toward the second side of the first wafer.

11. The method according to claim 9, wherein forming the point defects further comprises:
conducting a pre-treatment on the first side of the first wafer using at least one of a patterned approach or an unpatterned approach.

12. The method according to claim 9, wherein the first wafer is a device wafer and the second wafer is a handle wafer.

13. The method according to claim 9, wherein forming the transistor region further comprises:
forming a sinker region within the second epitaxial layer in alignment with the buried layer.

14. The method according to claim 13, wherein forming the transistor region further comprises:
forming a well region above the buried layer, and
forming an insulating layer above the trench feature, the insulating layer partially extending above the buried layer and the sinker region.

15. The method according to claim 14, wherein forming the transistor region further comprises:
forming a gate oxide over the well region;
forming a gate electrode over the gate oxide;
oxidizing the gate electrode;
forming a source region and a drain region in the well region, the source region and the drain region being on opposite sides of the gate electrode; and
forming a metal contact to the source region, the gate electrode, the drain region, and the sinker region.

16. A semiconductor structure comprising:
a first wafer including a device layer on a first side, the first wafer having a second side opposing the first side,
wherein the device layer includes:
a plurality of stacking faults positioned on a bottom portion of the device layer,
a buried layer positioned within the device layer above the plurality of stacking faults, and
a transistor region electrically connected to the buried layer; and
a second wafer bonded to the first side of the first wafer via a first oxide layer.

17. The semiconductor structure according to claim 16, further comprising:
a trench feature adjacent to the transistor region, the buried layer, and the plurality of stacking faults; and
a polysilicon layer located within the trench feature.

18. The semiconductor structure according to claim 16, wherein the device layer further comprises:
a first epitaxial layer positioned above the first oxide layer; and
a second epitaxial layer positioned above the buried layer.

19. The semiconductor structure according to claim 18, wherein each of the plurality of stacking faults is positioned at a point defect at an interface between the first wafer and the first epitaxial layer, the plurality of stacking faults propagates upward through the first epitaxial layer.

20. The semiconductor structure according to claim 18, wherein the plurality of stacking faults has at least one of a square shape or triangular shape, each of the plurality of stacking faults pointing toward the first side of the first wafer.
